(19) United States
(12) Patent Application Publication
(10) Pub. No.: US 2015/0064364 A1
(43) Pub. Date: Mar. 5, 2015

(54) Deposition System And Method Of Forming A Metalloid-Containing Material Therewith

(71) Applicant: Dow Corning Corporation, Midland, MI (US)

(72) Inventors: Binh Nguyen, Midland, MI (US); Michael Telgenhoff, Midland, MI (US)

(21) Appl. No.: 14/379,018

(22) PCT Filed: Feb. 14, 2013
(86) PCT No.: PCT/US2013/026134

§ 371 Date: Aug. 15, 2014

Related U.S. Application Data
(60) Provisional application No. 61/599,502, filed on Feb. 16, 2012.

(51) Int. Cl. C23C 16/452; C23C 16/448; H01J 37/34; C23C 16/50; C23C 14/35; C23C 16/44; C23C 16/48

(52) U.S. Cl. CPC C23C 16/452; C23C 16/44; C23C 16/448; C23C 16/48; C23C 16/50; C23C 14/35; H01J 37/3405
USPC 427/571; 427/569; 427/580; 427/595; 427/248.1; 118/600; 118/723 R; 118/620; 118/722; 204/192.12; 204/298.16

(57) ABSTRACT

A method of forming a metalloid-containing material comprises the step of preparing a hydrometalloid compound in a low volume on-demand reactor. The method further comprises the step of feeding the hydrometalloid compound prepared in the microreactor to a deposition apparatus. Additionally, the method comprises the step of forming the metalloid-containing material from the hydrometalloid compound via the deposition apparatus. A deposition system for forming the metalloid-containing material comprises at least one low volume on-demand reactor coupled to and in fluid communication with a deposition apparatus.

### BACKGROUND OF THE INVENTION

The subject invention generally relates to a deposition system and, more specifically, to a deposition system for forming a metalloid-containing material and to a method of forming the metalloid-containing material with the deposition system.

Metalloid compounds, such as hydrometalloid compounds, are well known in the art and are utilized in various applications. For example, certain hydrometalloid compounds are often utilized for deposition, such as chemical vapor deposition, to form metalloid-containing layers on substrates. However, the hydrometalloid compounds utilized for deposition may be pyrophoric, i.e., these hydrometalloid compounds may ignite spontaneously upon exposure to air and/or moisture. Accordingly, these conventional reactions pose great risk to equipment and human life. Additionally, because these hydrometalloid compounds are generally pyrophoric or at least flammable, it is difficult and precarious to store and/or transport these hydrometalloid compounds after their preparation and prior to their end use, e.g. chemical vapor deposition.

### SUMMARY OF THE INVENTION

The invention provides a method of forming a metalloid-containing material with a deposition system. In a first embodiment, the deposition system comprises at least one low volume on-demand reactor indirectly coupled to and in indirect fluid communication with a deposition apparatus. In this first embodiment, the method comprises preparing a hydrometalloid compound in the low volume on-demand reactor. This method further comprises indirectly feeding the hydrometalloid compound prepared in the low volume on-demand reactor to the deposition apparatus. Finally, the method comprises forming the metalloid-containing material with the deposition apparatus.

In a second embodiment, the deposition system comprises at least one low volume on-demand reactor coupled to and in fluid communication with a deposition apparatus. In this second embodiment, the method comprises preparing a hydrometalloid compound in the low volume on-demand reactor from a precursor compound including at least one substituent other than hydrogen bonded to a metalloid atom. This method further comprises feeding the hydrometalloid compound prepared in the low volume on-demand reactor to the deposition apparatus. Finally, the method comprises forming the metalloid-containing material with the deposition apparatus.

The invention also provides a deposition system for forming a metalloid-containing material. The deposition system comprises at least one low volume on-demand reactor for preparing a hydrometalloid compound. The deposition system further comprises a deposition apparatus indirectly coupled to and in indirect fluid communication with the at least one low volume on-demand reactor.

### DETAILED DESCRIPTION OF THE INVENTION

The invention provides a method of forming a metalloid-containing material and a deposition system for forming the metalloid-containing material. The deposition system and method are particularly suitable for forming metalloid-containing materials for use in photovoltaic cell modules. However, the deposition system and method may be utilized for forming metalloid-containing materials for use in other industries and applications beyond just photovoltaic cell modules.

The method of forming the metalloid-containing material utilizes a deposition system comprising at least one low volume on-demand reactor coupled to and in fluid communication with a deposition apparatus.

The low volume on-demand reactor prepares the hydrometalloid compound from a precursor compound. The low volume on-demand reactor may be any reactor having a total volume of the precursor compound of no more than 30, alternatively no more than 15, alternatively no more than 2, liters, so long as the reactor can initiate the preparation of the hydrometalloid compound from the precursor compound, or cease the preparation of the hydrometalloid compound from the precursor compound, in less than 60, alternatively less than 15, alternatively less than 2, minutes. The time periods set forth herein with respect to the ability of the low volume on-demand reactor to cease preparation of the hydrometalloid compound relate to conventional reactor shut-down procedures and not spontaneous and undesirable ceasing attributable to, for example, explosion of a reactor.

The precursor compound is selected based on a number of factors, such as the desired hydrometalloid compound and the low volume on-demand reactor employed. The precursor compound comprises at least one metalloid atom and may further comprise at least one substituent bonded to the metalloid atom, which may vary based on the low volume on-demand reactor employed and the particular reaction employed in the low volume on-demand reactor selected.

In certain embodiments, the low volume on-demand reactor is a microreactor. Microreactors have a much greater surface area to volume ratio than conventional reactors, and thus offer a much greater heat transfer per volume than conventional reactors. In certain embodiments, the microreactor defines at least one reaction chamber for preparing the hydrometalloid compound. The reaction chamber of the microreactor typically has a surface area to volume ratio of at least 1,500:1, alternatively at least 2,000:1, alternatively at least 2,250:1, alternatively at least 2,400:1, alternatively from 2,450:1 to 2,550:1. The microreactor typically has an overall volume of from 25 to 89, alternatively from 35 to 79, alternatively from 45 to 79, alternatively from 50 to 74, mL. However, the microreactor may have an overall volume greater or less than the overall volume set forth above contingent upon dimensions and size of the microreactor. Typically, a largest internal dimension of each volumetric space or reaction chamber of the microreactor is less than 1 mm. The overall volume referenced above relates to an internal volume defined by the microreactor in which the precursor compound and/or the hydrometalloid compound are present. The microreactor is generally formed from an inert material, such as glass, or a glass-based material, e.g. borosilicate glass. One example of a suitable microreactor is the Corning® Advanced-Flow™ reactor, commercially available from Corning Incorporated of Corning, New York. Another example of a suitable microreactor is described in U.S. Pat. No. 7,007,709, which is incorporated by reference herein in its entirety.

When the low volume on-demand reactor is the microreactor, the precursor compound is typically a halometalloid compound. The hydrometalloid compound is generally prepared from the halometalloid compound via reducing the halometalloid compound in the presence of a reducing agent.

The halometalloid compound may be any halometalloid compound having at least one metalloid-bonded halogen atom. The halogen atom may be a fluorine atom, a chlorine atom, a bromine atom, or an iodine atom. The halometalloid compound may include one metalloid atom or the halometalloid compound may comprise more than one metalloid atom, in which the metalloid atoms are typically bonded to one another. Alternatively, the halometalloid compound may comprise mixtures of different types of hydrometalloid compounds.

In embodiments in which the halometalloid compound includes but one metalloid atom, the halometalloid compound typically has the following general formula (1):

RₐH_{b}X_{4-a-b}Si,

wherein each R is independently selected from a substituted hydrocarbyl group, an unsubstituted hydrocarbyl group and an amino group, each X is independently a halogen atom, and a and b are each independently an integer from 0 to 3 with the proviso that a+b equals an integer from 0 to 3. Because a+b equals an integer from 0 to 3, the halogenated monosilane compound implicitly includes at least one silicon-bonded halogen atom, which is represented by X in the general formula above.

When the halometalloid compound includes more than one metalloid atom, the halometalloid compound typically has the following general formula (2):

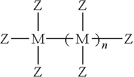

wherein each Z is independently selected from a substituted hydrocarbyl group, an unsubstituted hydrocarbyl group, an amino group, a hydrogen atom, and a halogen atom, with the proviso that at least one Z is a halogen atom, M is an independently selected metalloid atom, and n is an integer from 1 to 20, alternatively from 1 to 5, alternatively from 1 to 3, alternatively 3, alternatively 2, alternatively 1.

Reducing the halometalloid compound in the microreactor and in the presence of the reducing agent produces the hydrometalloid compound, which includes at least one more metalloid-bonded hydrogen atom than the halometalloid compound, if any. Consequently, the halometalloid compound includes at least one more silicon-bonded halogen atom than the halometalloid compound, if any. Said differently, reducing the halometalloid compound typically comprises formally replacing at least one metalloid-bonded halogen atom of the halometalloid compound with at least one hydrogen atom to produce the hydrometalloid compound. More than one metalloid-bonded halogen atom of the halometalloid compound may be reduced, i.e., formally replaced, with hydrogen atoms, dependent upon the number of metalloid-bonded halogen atoms of the halometalloid compound. In certain embodiments, reducing the halometalloid compound comprises replacing every metalloid-bonded halogen atom of the halometalloid compound with a hydrogen atom to produce the hydrometalloid compound. As but one example, when the halometalloid compound comprises four metalloid-bonded halogen atoms, the hydrometalloid compound produced by reducing the halometalloid compound may include four metalloid-bonded hydrogen atoms, three metalloid-bonded hydrogen atoms and one metalloid-bonded halogen atom, two metalloid-bonded hydrogen atoms and two metalloid-bonded halogen atoms, or one metalloid-bonded hydrogen atom and three metalloid-bonded halogen atoms.

The halometalloid compound is reduced in the microreactor in the presence of the reducing agent. Typically, the reducing agent comprises a metal hydride, although the reducing agent can be any compound suitable for reducing the halometalloid compound. The metal hydride can be any metal hydride capable of converting at least one of the metalloid-bonded halogen atoms of the halometalloid compound to metalloid-bonded hydrogen atoms. Metal hydrides suitable for the purposes of the present invention include hydrides of sodium, magnesium, potassium, lithium, boron, calcium, titanium, zirconium, and aluminum. The metal hydride can be a simple (binary) metal hydride or a complex metal hydride. Most typically, the reducing agent is in the form of a liquid comprising the reducing agent, e.g. the metal hydride, such that the reducing agent can be fed into the microreactor without clogging or otherwise blocking microchannels defined by the microreactor. Additionally, during the step of reducing the halometalloid compound, the reducing agent is often converted to a halide salt. Accordingly, the reducing agent is typically selected such that the halide salt of the reducing agent is also a liquid to prevent clogging of the microchannels defined by the microreactor.

Specific examples of the reducing agent and additional aspects regarding the reduction of the halometalloid when the metalloid of the halometalloid is silicon are disclosed in co-filed and co-pending Application Ser. No. 61/599,505, which is herein incorporated by reference herein in its entirety. The silicon atoms of the compounds disclosed in this reference may be substituted by other metalloid atoms.

In other embodiments, the low volume on-demand reactor is a plasma reactor. The plasma reactor typically prepares the hydrometalloid compound from contacting the precursor compound and a plasma. Specific examples of the precursor compound that may be utilized in the plasma reactor to prepare the hydrometalloid compound include materials containing a silica (SiO₂), elemental metalloids (e.g. Si, Ge, etc.), metalloid-containing compounds (e.g. silicates, silicon carbides, silicon polymers, and the like). The plasma is typically a hydrogen plasma and/or an inert gas plasma. The plasma is generally formed from a plasma input gas in a plasma generating device and fed to the plasma reactor for contacting the precursor compound. In particular, the plasma and the precursor compound are typically contacted in a reaction chamber defined by the plasma reactor to prepare the hydrometalloid compound. Examples of a suitable plasma reactor are disclosed in United States Published Patent Application Nos. 2011/0206591 and 2011/0206592, which are incorporated by reference herein in their respective entireties.

As but one example of the reaction to form the hydrometalloid compound in the plasma reactor, the precursor compound may be an elemental metalloid, such as elemental silicon, and the plasma may be hydrogen plasma. In this example, contacting the elemental silicon with the hydrogen plasma results in the production of monosilane via the following reaction formula: Si₍ₛ₎+2H₂→SiH₄.

In yet other embodiments, the low volume on-demand reactor is a silent electric discharge (SED) reactor. Alternatively, the low volume on-demand reactor may be a UV reactor. Generally, when the low volume on-demand reactor is the SED reactor or the UV reactor, the precursor compound comprises a metalloid compound having all metalloid-bonded hydrogen atoms. In these embodiments, the hydrometalloid compound formed in the low volume on-demand reactor is a polyhydrometalloid formed from the precursor compound in which the metalloid atoms are bonded directly to one another in series. For example, when the metalloid of the precursor compound is silicon, the precursor compound may be SiH₄, which forms Si₂H₆+H₂ in the low volume on-demand reactor. The hydrogen gas produced in such a reaction may be recycled and utilized in the deposition apparatus or captured for other uses.

The method further comprises the step of feeding the hydrometalloid compound prepared in the low volume on-demand reactor to the deposition apparatus. The hydrometalloid compound is typically fed in real time to the deposition apparatus as the hydrometalloid compound is prepared in the low volume on-demand reactor such that the hydrometalloid compound need not be stored and/or transported after being prepared but prior to being fed to the deposition apparatus.

In a first embodiment, the low volume on-demand reactor is indirectly coupled to and in indirect fluid communication with the deposition apparatus. In this first embodiment, the hydrometalloid compound is indirectly fed to the deposition apparatus from the low volume on-demand reactor. When the low volume on-demand reactor is indirectly coupled to and in indirect fluid communication with the deposition apparatus, the precursor compound may be any precursor compound suitable for the preparation of the hydrometalloid compound in the low volume on-demand reactor.

In a second embodiment, the low volume on-demand reactor is coupled to and in fluid communication with the deposition apparatus. In this second embodiment, the low volume on-demand reactor may be indirectly coupled to and in indirect fluid communication with the deposition apparatus. Alternatively, in this second embodiment, the low volume on-demand reactor may be directly coupled to and in direct fluid communication with the deposition apparatus. The low volume on-demand reactor is directly coupled to and in direct fluid communication with the deposition apparatus when the hydrometalloid compound is fed to the deposition apparatus from the low volume on-demand reactor without being further processed or modified via discrete processing apparatuses that may optionally be utilized to establish indirect coupling and indirect fluid communication between the low volume on-demand reactor and the deposition apparatus. For example, the hydrometalloid compound may be fed from the low volume on-demand reactor via various piping or other mechanisms, which may optionally include a shut-off valve or other valve for modifying flow of the hydrometalloid compound, while the low volume on-demand reactor and the deposition apparatus are still considered to be directly coupled to one another and in direct fluid communication with one another. Said differently, the deposition system may further include a valve that may optionally stop flow of the hydrometalloid compound from the low volume on-demand reactor to the deposition apparatus yet the low volume on-demand reactor and the deposition apparatus are still referred to as being directly coupled to one another so as to distinguish from embodiments including the at least one processing apparatus, which establishes indirect coupling and indirect fluid communication between the low volume on-demand reactor and the deposition apparatus. Regardless of the particular deposition system utilized in this second embodiment, the precursor compound employed in the second embodiment includes at least one substituent other than hydrogen bonded to a metalloid atom. For example, when the metalloid of the hydrometalloid compound is silicon, the precursor compound includes at least one silicon-bonded substituent other than silicon-bonded hydrogen such that the precursor compound is other than monosilane (SiH₄). However, the precursor compound may still include one or more metalloid-bonded hydrogen atoms so long as the precursor compound includes at least one substituent other than hydrogen bonded to a metalloid atom. To this end, the SED reactor and the UV reactor are generally utilized in the first embodiment described above because these reactors typically utilize precursor compounds having only metalloid-bonded hydrogen atoms.

In the first and/or the second embodiment set forth above, the deposition system may include a plurality of low volume on-demand reactors coupled to and in fluid communication with the deposition apparatus. The low volume on-demand reactors are typically positioned such that the flow of the respective hydrometalloid compounds prepared in the low volume on-demand reactors are fed in parallel with one another to the deposition apparatus. Alternatively, the deposition system may include a plurality of low volume on-demand reactors that are in series with one another, either for purposes of increasing yield of the hydrometalloid compound or for employing a series of various sequential reactions.

In certain embodiments, the deposition system further comprises at least one processing apparatus which is disposed between, coupled to and in fluid communication with the low volume on-demand reactor and the deposition apparatus. The presence of the at least one processing apparatus establishes indirect coupling and indirect fluid communication from the low volume on-demand reactor to the deposition apparatus via the processing apparatus. To this end, the low volume on-demand reactor is indirectly coupled to an in indirect fluid communication with the deposition apparatus when the at least one processing apparatus is employed in the deposition system even in the second embodiment described above.

Indirect coupling and indirect fluid communication may be distinguished from direct coupling and direct fluid communication via the at least one processing apparatus. For example, when the deposition system includes the at least one processing apparatus, the low volume on-demand reactor is not referred to as having direct fluid communication with the deposition apparatus because the hydrometalloid compound is diverted to the at least one processing apparatus prior to being fed to the deposition apparatus. However, even indirect coupling and indirect fluid communication is distinguished from a method in which the hydrometalloid compound is disposed in a storage tank prior to feeding the hydrometalloid compound to the deposition apparatus.

When the deposition system includes the at least one processing apparatus, the method further comprises the step of processing the hydrometalloid compound prepared in the low volume on-demand reactor in the processing apparatus prior to feeding the hydrometalloid compound to the deposition apparatus.

The processing apparatus may comprise a heat exchanger, a mixer, a compressor, a pump, a stripper, a separator, and/or a purification apparatus. When the processing apparatus comprises the purification apparatus and the purification apparatus is included in the deposition system, the method further comprises purifying the hydrometalloid compound with the purification apparatus prior to feeding the hydrometalloid compound to the deposition apparatus. The purification apparatus is generally utilized to remove unwanted byproducts and impurities present along with the hydrometalloid compound from the preparation of the hydrometalloid compound in the low volume on-demand reactor. The purification apparatus may remove unwanted byproducts and impurities by, for example, filtering, catalytic conversion, dehydrating, sequestering, extracting, and combinations thereof. For example, when the hydrometalloid compound is prepared in the microreactor from the halometalloid compound, the purification apparatus is generally utilized to remove various impurities including CO₂, H₂O, and by-products from the reduction reaction (e.g. disiloxane when the metalloid is silicon), which are generally present along with the hydrometalloid compound at an outlet of the microreactor. Generally, the hydrometalloid compound is in a gaseous phase, and the purification apparatus also removes any solid impurities from the gaseous phase. One example of a purification apparatus suitable for the deposition system is a PG Series Gaskleen® Gas Purifier, commercially available from Pall Corporation of Port Washington, N.Y.

The purification apparatus may utilize a packed bed. For example, the packed bed may utilize a modified molecular sieve for removing impurities from the hydrometalloid compound. One example of such a packed bed is disclosed in United States Patent Application No. 2002/0028167, which incorporated by reference herein in its entirety. Another example of a packed bed which utilizes a heated carbon bed is disclosed in U.S. Pat. No. 5,290,342, which is incorporated by reference herein in its entirety.

Alternatively, the purification apparatus may utilize various methods of adsorption and/or filtration. For example, the purification apparatus may utilize an organic resin for removing unwanted impurities, such as metal impurities, from the hydrometalloid compound. One example of such a purification apparatus utilizing an organic resin is disclosed in United States Patent Application No. 2011/0184205, which incorporated by reference herein in its entirety.

The deposition system may include more than one processing apparatus. For example, the deposition system may include more than one purification apparatus, e.g. two or more different purification apparatuses or two or more of the same purification apparatus. The deposition system may include one purification apparatus in combination with another processing apparatus other than a purification apparatus. Further, the deposition system may include two or more processing apparatuses other than purification apparatuses in combination with one another.

The deposition apparatus is generally selected based upon the desired method of forming the metalloid-containing material and may be any deposition apparatus known by those of skill in the art.

In certain embodiments, the deposition apparatus comprises a chemical vapor deposition apparatus. In these embodiments, the deposition apparatus is typically selected from a thermal chemical vapor deposition apparatus, a plasma enhanced chemical vapor deposition apparatus, a photochemical vapor deposition apparatus, an electron cyclotron resonance apparatus, an inductively coupled plasma apparatus, a magnetically confined plasma apparatus, and a jet vapor deposition apparatus. The optimum operating parameters of each of these chemical deposition vapor apparatuses based upon the particular hydrometalloid compound prepared in the low volume on-demand reactor and the desired application in which the metalloid-containing material formed via the deposition apparatus is utilized. In certain embodiments, the deposition apparatus comprises a plasma enhanced chemical vapor deposition apparatus. In other embodiments, the deposition apparatus comprises a thermal chemical vapor deposition apparatus.

In other embodiments, the deposition apparatus comprises a physical vapor deposition apparatus. In these embodiments, the deposition apparatus is typically selected from a sputtering apparatus, an atomic layer deposition apparatus, and a DC magnetron sputtering apparatus. The optimum operating parameters of each of these physical deposition vapor apparatuses based upon the particular hydrometalloid compound prepared in the low volume on-demand reactor and the desired application in which the metalloid-containing material formed via the deposition apparatus is utilized. In certain embodiments, the deposition apparatus comprises a sputtering apparatus. The sputtering apparatus may be, for example, an ion-beam sputtering apparatus, a reactive sputtering apparatus, an ion-assisted sputtering apparatus, etc.

Additionally, the method comprises the step of forming the metalloid-containing material from the hydrometalloid compound via the deposition apparatus. The particular form of the metalloid-containing material is contingent on the particular hydrometalloid compound employed in the deposition apparatus and the particular deposition apparatus utilized.

For example, the metalloid-containing material may be elemental metalloid, such as elemental silicon, elemental germanium, etc. In these embodiments, the elemental metalloid may be crystalline, i.e., monocrystalline or polycrystalline, or amorphous, or combinations thereof. Such elemental metalloids may be in the form of films. Alternatively, the elemental metalloid may be deposited in the form of nanoparticles, which are generally amorphous, but may also be monocrystalline and/or polycrystalline. Further, the elemental metalloid may be deposited in the form of a rod, or in the form of a powder or flakes. Generally, such rods and/or powders are crystalline. However, the metalloid-containing material may include other atoms such that the metalloid-containing material is not an elemental metalloid. As but one example, when the metalloid is silicon, the metalloid-containing material formed via the deposition apparatus may be silica, e.g. silica nanoparticles, which comprises SiO_{4/2} units.

The metalloid-containing material may be deposited on a substrate. The substrate is generally referred to in the art as a wafer, and may comprise any suitable material, such as silicon.

The metalloid-containing material is suitable in many diverse applications. One exemplary example of an application in which the metalloid-containing material may be utilized is photovoltaic cell layers in photovoltaic cell modules. The metalloid-containing material may also be utilized in other semiconductor devices. Alternatively, the metalloid-containing material may be utilized as or to form an insulating film or a dielectric layer.

As introduce above, the subject invention also provides a deposition system for forming the metalloid-containing material on the substrate. The deposition system comprises the at least one microreactor for preparing the hydrometalloid compound. The deposition system further comprises the deposition apparatus indirectly coupled to and in indirect fluid communication with the at least one microreactor for forming the metalloid-containing material from the hydrometalloid compound.

The method obviates many concerns and risks associated with conventional methods of preparing hydrometalloid compounds and methods of preparing metalloid-containing materials from hydrometalloid compounds. For example, various hydrometalloid compounds, as well as their precursor compounds, are pyrophoric. To this end, manufacturers located in industrial parks generally do not store hydrometalloid compounds due to the risk posed to equipment and life. Rather, these manufacturers purchase small quantities of hydrometalloid compounds and deposit them to form metalloid-containing materials via a batch process. Specifically, small amounts of hydrometalloid compounds are typically obtained from manufacturers/suppliers in a cylinder, and once the cylinder is empty, the cylinder is returned to the manufacturer/supplier and the process is shut down or switched to stand-by until the cylinder is returned (and once again containing small quantities of the hydrometalloid compound). In contrast, the instant method is typically a continuous method. As such, the hydrometalloid compound prepared in the low volume on-demand reactor is generally continuously deposited to form the metalloid-containing material via the deposition apparatus, thereby increasing efficiency and output while minimizing costs associated with the transportation and storage of hydrometalloid compounds. In fact, while the deposition system and method may be utilized to continuously form the metalloid-containing material, each deposition system includes no more than 30 liters of the precursor compounds and/or the hydrometalloid compound, thereby reducing risks associated with the pyrophoricity of such compounds. Further, when the deposition system includes the purification apparatus, the hydrometalloid compound can be sufficiently purified in real time as it is prepared in the low volume on-demand reactor to obviate concerns relating to the deposition of hydrometalloid compound including undesirable impurities. Accordingly, the method is typically continuous regardless of whether the low volume on-demand reactor and the deposition apparatus are indirectly coupled to and in indirect fluid communication with one another or whether the low volume on-demand reactor and the deposition apparatus are directly coupled to and in direct fluid communication with one another. Additionally, certain low volume on-demand reactors utilize a carrier gas, e.g. hydrogen gas, along with the precursor compound, and such a carrier gas may be reused or otherwise recycled by certain deposition apparatuses, thereby reducing costs associated with such carrier gasses.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

The following examples are intended to illustrate embodiments of the invention and are not to be viewed in any way as limiting to the scope of the invention.

### EXAMPLES

### Prophetic Example 1

A precursor compound comprising a halometalloid compound is reduced in a low volume on-demand reactor in the presence of a reducing agent to produce a hydrometalloid compound. In particular, the low volume on-demand reactor is a microreactor and the halometalloid compound is SiCl₄. The halometalloid compound is reduced in the low volume on-demand reactor in the presence of a reducing agent, LiAlH₄. The reaction product of the reduction reaction includes a hydrometalloid compound, i.e., SiH₄. The reaction product of the reduction reaction is a gas and further includes various by-products and impurities, such as disiloxane (H₃SiOSiH₃), CO₂, PH₃, and H₂O. The reaction product including the hydrometalloid compound is fed to a purification apparatus for removing the disiloxane, CO₂, H₂O, and solid impurities therefrom to form a purified reaction product. The purified reaction product is then fed to a packed bed of 50% zinc substituted 3A molecular sieves to remove impurities, e.g. PH₃. The packed bed is about 12 inches long and 0.5 inches in diameter. The hydrometalloid compound exits the packed bed and is fed to a deposition apparatus. The deposition apparatus combines the hydrometalloid compound with hydrogen gas and forms a silicon layer on a substrate comprising a silicon wafer via epitaxial deposition.

### Prophetic Example 2

A precursor compound comprising a halometalloid compound is reduced in a low volume on-demand reactor in the presence of a reducing agent to produce a hydrometalloid compound. In particular, the low volume on-demand reactor is a microreactor and the halometalloid compound is GeCl₄. The halometalloid compound is reduced in the low volume on-demand reactor in the presence of a reducing agent, LiAlH₄. The reaction product of the reduction reaction includes a hydrometalloid compound, i.e., GeH₄. The reaction product of the reduction reaction is a gas and further includes various by-products and impurities, such as disiloxane (H₃SiOSiH₃), CO₂, PH₃, and H₂O. The reaction product including the hydrometalloid compound is fed to a purification apparatus for removing the disiloxane, CO₂, H₂O, and solid impurities therefrom to form a purified reaction product. The purified reaction product is then fed to a packed bed of 50% zinc substituted 3A molecular sieves to remove impurities, e.g. PH₃. The packed bed is about 12 inches long and 0.5 inches in diameter. The hydrometalloid compound exits the packed bed and is fed to a deposition apparatus. The deposition apparatus combines the hydrometalloid compound with hydrogen gas and forms a germanium layer on a substrate comprising a silicon wafer via epitaxial deposition.

### Prophetic Example 3

A precursor compound comprising elemental silicon and hydrogen plasma are contacted in a low volume on-demand reactor. Specifically, the elemental silicon and the hydrogen plasma are contacted in a plasma reactor to form a hydrometalloid compound, i.e., SiH₄. The hydrometalloid is then fed directly to a deposition apparatus via stainless steel piping, and the deposition apparatus forms a silicon layer on a substrate comprising a silicon wafer via epitaxial deposition.

1. A method of forming a metalloid-containing material with a deposition system which comprises at least one low volume on-demand reactor indirectly coupled to and in indirect fluid communication with a deposition apparatus, said method comprising the steps of:
preparing a hydrometalloid compound in the low volume on-demand reactor;
indirectly feeding the hydrometalloid compound prepared in the low volume on-demand reactor to the deposition apparatus; and
forming the metalloid-containing material with the deposition apparatus.

2. A method of forming a metalloid-containing material with a deposition system which comprises at least one low volume on-demand reactor coupled to and in fluid communication with a deposition apparatus, said method comprising the steps of:
preparing a hydrometalloid compound in the low volume on-demand reactor from a precursor compound including at least one substituent other than hydrogen bonded to a metalloid atom;
feeding the hydrometalloid compound prepared in the low volume on-demand reactor to the deposition apparatus; and
forming the metalloid-containing material with the deposition apparatus.

3. The method of claim 1 wherein the deposition system further comprises at least one processing apparatus which is disposed between, coupled to and in fluid communication with the low volume on-demand reactor and the deposition apparatus so as to establish indirect coupling and indirect fluid communication from the low volume on-demand reactor to the deposition apparatus via the processing apparatus and the method further comprises the step of processing the hydrometalloid compound prepared in the low volume on-demand reactor in the processing apparatus prior to feeding the hydrometalloid compound to the deposition apparatus.

4. The method of claim 3 wherein the processing apparatus comprises a purification apparatus and the method further comprises the step of purifying the hydrometalloid compound with the purification apparatus prior to feeding the hydrometalloid compound to the deposition apparatus.

5. The method of claim 2 wherein the low volume on-demand reactor is directly coupled to and in direct fluid communication with the deposition apparatus such that the hydrometalloid compound is fed directly from the low volume on-demand reactor to the deposition apparatus.

6. The method of claim 2 wherein the low volume on-demand reactor is indirectly coupled to and in indirect fluid communication with the deposition apparatus such that the hydrometalloid compound is fed indirectly from the low volume on-demand reactor ultimately to the deposition apparatus.

7. The method of claim 1 wherein the low volume on-demand reactor is selected from microreactors, plasma reactors, silent electric discharge reactors, UV reactors, and combinations thereof.

8. The method of claim 1 wherein the deposition apparatus comprises a chemical vapor deposition apparatus selected from a thermal chemical vapor deposition apparatus, a plasma enhanced chemical vapor deposition apparatus, a photochemical vapor deposition apparatus, an electron cyclotron resonance apparatus, an inductively coupled plasma apparatus, a magnetically confined plasma apparatus, and a jet vapor deposition apparatus.

9. The method of claim 1 wherein the deposition apparatus comprises a physical vapor deposition apparatus selected from a sputtering apparatus, an atomic layer deposition apparatus, and a DC magnetron sputtering apparatus.

10. A deposition system for forming a metalloid-containing material, said deposition system comprising:
at least one low volume on-demand reactor for preparing a hydrometalloid compound; and
a deposition apparatus indirectly coupled to and in indirect fluid communication with said at least one low volume on-demand reactor.

11. The deposition system of claim 10 further comprising a processing apparatus disposed between and coupled to and in fluid communication with said low volume on-demand reactor and said deposition apparatus so as to establish indirect coupling and indirect fluid communication from said low volume on-demand reactor to said deposition apparatus via said processing apparatus.

12. The deposition system of claim 11 wherein said processing apparatus comprises a purification apparatus, a catalytic reactor, or combinations thereof.

13. The deposition system of claim 10 wherein said low volume on-demand reactor is selected from microreactors, plasma reactors, silent electric discharge reactors, UV reactors, and combinations thereof.

14. The deposition system of claim 10 wherein said deposition apparatus comprises a chemical vapor deposition apparatus selected from a thermal chemical vapor deposition apparatus, a plasma enhanced chemical vapor deposition apparatus, a photochemical vapor deposition apparatus, an electron cyclotron resonance apparatus, an inductively coupled plasma apparatus, a magnetically confined plasma apparatus, and a jet vapor deposition apparatus.

15. The deposition system of claim 10 wherein said deposition apparatus comprises a physical vapor deposition apparatus selected from a sputtering apparatus, an atomic layer deposition apparatus, and a DC magnetron sputtering apparatus.

16. The method of claim 2 wherein the deposition system further comprises at least one processing apparatus which is disposed between, coupled to and in fluid communication with the low volume on-demand reactor and the deposition apparatus so as to establish indirect coupling and indirect fluid communication from the low volume on-demand reactor to the deposition apparatus via the processing apparatus and the method further comprises the step of processing the hydrometalloid compound prepared in the low volume on-demand reactor in the processing apparatus prior to feeding the hydrometalloid compound to the deposition apparatus.
